(19) United States
(12) Patent Application Publication
(10) Pub. No.: US 2010/0071936 A1
(43) Pub. Date: Mar. 25, 2010

(54) Thermally-Efficient Metal Core Printed Circuit Board With Selective Electrical And Thermal Connectivity

(75) Inventor: Kia Kuang Tan, Penang (MY)

Correspondence Address: PATENT LAW GROUP LLP, 2635 NORTH FIRST STREET, SUITE 223, SAN JOSE, CA, 95134, US

(73) Assignee: DSEM HOLDINGS SDN. BHD., Penang (MY)

(21) Appl. No.: 12/594,196

(22) PCT Filed: Apr. 4, 2008
(86) PCT No.: PCT/MY2008/000028

§ 371 Date: Sep. 30, 2009

(30) Foreign Application Priority Data
Apr. 5, 2007 (MY) PI 20070532

(51) Int. Cl. H05K 1/00; H05K 1/11; H05K 1/09

(52) U.S. Cl. 174/252; 174/266; 174/257; 174/256; 174/258

(57) ABSTRACT

Methods for controlling thermal conductivity paths in a metal core circuit board, as well as methods to provide selective electrical isolation, are described. In one embodiment, grooves are formed in an aluminum substrate surrounding areas where electrical components are to be mounted on the substrate. The grooves are oxidized along with the opposing surface of the substrate to create a vertical oxide ring around the area for electrical and lateral thermal isolation. This also allows the substrate to be made relatively thick for mechanical strength. Other features include forming copper around oxidized sides of the substrate for connection between top and bottom copper layers; plating up copper to be co-planar with a raised dielectric layer; forming indentions in the substrate for containing a dielectric so the dielectric is co-planar with the remaining surface; forming copper vias through the substrate; and planarizing the substrate surface so that conductors and dielectric layers are co-planar.

### FIELD OF THE INVENTION

This invention relates to a metal core circuit board that provides high in-plane and through-plane thermal conductivity between an electronic device (e.g., a semiconductor chip) and a heat sink, and provides selective electrical isolation and electrical interconnections.

### BACKGROUND

The need for high thermal performance printed circuit boards or substrates is well known in the electronic industry. Although metal core printed circuit boards and other insulated heat-sinking substrates have been in used for many years, these known prior art substrates for electronic circuits have known deficiencies.

FIG. 1A is a typical prior art metal core printed circuit board. It comprises metal base 1, a resin-base dielectric layer 2 laminated onto the metal base, and a layer of copper foil 3 laminated onto the dielectric layer 2. The copper foil 3 is etched to be a printed circuit. Electronic components may then be soldered to lines and pads formed by the patterned copper foil. The adhesive used for the dielectric layer 2 and copper foil 3 has a relatively low glass transition temperature, Tg, which may result in low copper peel strength and other thermo-mechanical related failures over high temperature exposure.

In FIG. 1B, the laminated dielectric layer 2 is 75-100 microns thick, and a thick copper foil 3 of 70-105 microns is used for electrical interconnections and for heat spreading purposes.

FIG. 1C illustrates a variation of FIG. 1B where there is formed an opening 6 in the dielectric layer 2 (e.g., 75 microns thick) so a thermal pad (not shown) on the electronic component can be directly affixed to the metal base. To maintain a planar surface for mounting of the heat-producing dies, the thickness of the thermal pad must equal the combined thickness of the dielectric layer 2 and the copper foil 3. However, the thicker the thermal interface material (i.e., the thermal pad), the higher the thermal resistance of the heat source path. The thermal pad is typically a metal epoxy or thermal grease that is compressed by the die.

Another prior art metal circuit board uses an anodic coating as the dielectric layer, with the copper foil laminated over the anodic coating. In an anodic coating, a film of oxide is produced on a metal by electrolysis with the metal as the anode. The dielectric layer provides the electrical isolation between the copper circuit layer and the metal core. A thick dielectric layer provides good electrical breakdown performance. On the other hand, a thicker dielectric layer adds thermal resistance to the stacked up structure.

Some prior art circuit designs attempt to work around these conflicting properties by electrically isolating the electrical connections from the bulk metal base using a very thin layer of thermally conductive dielectric which, if too thin, will result in lower breakdown voltage. If too thick, the thermal resistance will increase accordingly.

What is needed is a more thermally efficient and reliable thermal circuit board for heat-generating dies and other electronic circuits.

### SUMMARY

This invention relates to a thermally-efficient metal core printed circuit board with enhanced in-plane and through-plane thermal conductivity performance for high power or heat sensitive electronic device applications. More particularly, this invention relates to the manufacture of an aluminum metal core substrate using selective isolation techniques resulting in close to bulk metal thermal conductivity for the thermal path and controllable high breakdown voltage protection for the electrical circuitries.

The electrical insulation is provided by aluminum oxide formed in an aluminum substrate co-planar with the surface of the base metal substrate. Selective anodization is used for electrical isolation. Metal sputtering and additive copper plating are used for forming co-planar metal layers for thermal pads and electrical interconnects. Since there is no adhesive system (no lamination) in the process, the resulting substrate can withstand high temperature operation with no thermo-mechanical failures like delamination or inner-layer blistering.

In summary, the invention relates to a cost-effective highly thermally efficient and robust printed circuit board or substrate for the electronic industry. The circuit board is comprised of a metal base material with opposing first and second faces and electrical interconnects, electrically isolated from the base metal, for electronic device assembly. The electronic devices mounted on the circuit board can be any number of devices such as packaged integrated circuits, multi-chip modules, transistors, resistors, capacitors, Light Emitting Diodes (LED), and the like. When operated, the active devices dissipate energy in the form of heat. Die packages can be vertically stacked to form a multi-layer 3-D structure, and the high heat can be efficiently removed by the circuit board.

For discussion purposes, an LED is used to illustrate the operation of the invention. An LED has very high heat density because of the tiny light source. About 85% of the power into the LED is converted to heat. The drive to increase brightness in the tiny light source requires higher power, resulting in a rapid increase in device junction temperature. The increase in temperature translates to poor light extraction efficiency and high device failure rate. In general, the device failure rate doubles for every 10 degree C. rise in junction temperature. A heat sink is used to help dissipate the generated heat. The heat sink adds to the overall product cost.

Generally, a high percentage of the heat is conducted downwards from the device to the circuit board, so that a low vertical thermal resistance (through the circuit board plane to a larger heat sink) will result in an optimum thermal conduction path for the heat source.

The through-plane thermal resistance increases with the number of stacked up layers for the multi-layer circuit board. With device miniaturization, heat density increases many fold. In-plane circuit board heat spreading will help distribute heat away from the hot spots. The efficiency of heat spreading and heat conduction vertically through the circuit board is an important factor in how well heat can be transferred from an electronic device to the ambient air. The traditional fiber glass or epoxy based printed circuit is not a good thermal conductor vertically and laterally. This is mainly due to the thin interspersed and discontinuous metal and non-metal layers.

Thermal vias, multi-layer copper planes, and a metal core with an embedded (oxidized) dielectric layer are used to alleviate the heat problem. The present invention aims to reduce the thermal interface resistance by providing a planar surface for device assembly, where thermal pads and metal interconnects are co-planar. The design challenge is to create a cost-effective thermally efficient metal core circuit board with a planar surface for electrical and thermal circuitries. One goal is a thermally-efficient metal core printed circuit board with enhanced in-plane and through-plane thermal conductivity performance for high power or heat sensitive electronic device applications.

More particularly, this invention relates to the manufacture of an aluminum metal core substrate using selective insulation and metallization techniques resulting in close to bulk metal thermal conductivity for the thermal path and programmable high breakdown voltage protection for the electrical circuitries. The electrical insulation is provided by an aluminum oxide layer in the aluminum base. In another embodiment, the dielectric layer can be formed by methods such as surface resin coating, Plasma Electrolytic Oxidation, and other techniques that do not laminate a layer onto the metal base. The selective anodization, or coating, and the metal sputtering and additive copper plating over the insulation or directly on the metal base, allows selective surface insulation, selective embedded insulation, and vertical via electrical isolation.

In accordance with one embodiment of the present invention, a thermally-efficient metal core printed circuit board comprises an aluminum base including an opposing first face and second face, with the faces having a plurality of dispersed dielectric layer areas embedded within the metal base resulting in a planar surface for the overlying circuitries, a plurality of dispersed thermal metallization layer areas (thermal pads) formed directly on the metal base for optimum thermal performance, and a plurality of electrical circuits mounted over the metal base and electrically and thermally connected to the various co-planar thermal pads and metal interconnections. The planar surface is important for flat surface mounting technology and flip-chip devices assembly. The selective dielectric layer configuration allows direct thermal pad contact to the bulk metal base and insulation for the electrical terminals, resulting in a highly thermally-efficient circuit board for single or matrix device assembly or mother-board applications. The selective dielectric and metallization topology is also applicable to a 3D heat sink structure.

In accordance with one embodiment of the present invention, the dielectric layer is selectively formed using known art photo-lithography masking steps and anodic coating processes. Additional planarization steps may be used, such as etching, deburring, or plating-up metallization to create the planar surface critical for surface mount devices. The metallization steps may use copper plating, silver (or other metal) printing, or sputtering.

In one embodiment, the dielectric is selectively grown (as an oxide) on top of the metal base for electrical isolation purposes. Electrical circuits are then plated directly on top of the dielectric area for electrical isolation and breakdown voltage capability.

In one embodiment, a thermal pad is directly plated on the non-oxidized metal surface of the metal base, resulting in negligible thermal resistance or close to bulk metal thermal conductivity per unit area.

In one embodiment, the selective isolation methodology on the circuit board produces improved thermal performance and a higher breakdown voltage capability compared to prior art composite material methodology where both the electrical and thermal pads sit on the same dielectric insulation layer.

In one embodiment, grooves are formed in the metal substrate to surround areas where electrical components are to be mounted. The grooves are oxidized along with areas of the substrate on the opposite surface so that the oxides on both sides grow toward each other and merge. This creates electrically isolated islands for the electrical components and allows the substrate to be an electrical conductor for the components. This also laterally thermally isolates the components. Such a technique enables the use of relatively thick substrates that are more rugged than prior art substrates, where the prior art substrates must be less than 400 um thick to enable the merging of up-down oxide growth through the entire substrate thickness.

The basic planar metal circuit board structure can be extended to a 3-D heat sink structure where the planar face comprises a plurality of selectively insulated electrical circuits and a plurality of thermal pads connected directly to the metal base.

The invention is applicable to a copper base where the dielectric layer can be selectively printed onto the copper base. The dielectric can be sputtered on a etched surface so that the finished dielectric layer is in the same plane as the rest of the copper metal surface or the direct-contact thermal pad area is copper plated up to achieve the planar surface. The process steps can be repeated, resulting in a thicker substrate with vertical vias that can provide a copper electrical connection or a copper thermal path.

### BRIEF DESCRIPTION OF THE DRAWINGS

FIG. 1A is a perspective view of a prior art laminated insulated metal core board. It has a copper layer laminated on to a dielectric layer covering the whole surface of the metal base.

FIG. 1B is a cross-sectional view of a laminated dielectric layer overlying the whole metal base, with copper layer portions over the dielectric layer.

FIG. 1C is a cross-sectional view of a metal base with an opening in a dielectric layer for a thermal pad. Since there is no copper in the thermal pad area, the thermal connection is done using a compressible thermal interface material, such as a metal epoxy or thermal grease.

FIG. 2A′ is a top view of an embodiment of the present invention with cross-sectional views across lines A, B, C, and D.

FIG. 2A″ is a bottom view of the embodiment of FIG. 2A′ with cross-sectional views along lines E and F of FIG. 2A′.

FIG. 2B′ is a top view of a metal base only, without any metal or dielectric pattern shown.

FIG. 2B″ is a cross-sectional view of the embodiment of FIG. 2B′ showing metal and dielectric patterns along line A-A of FIG. 2B′.

FIG. 3A is a top view of a metal base only, without any metal or dielectric pattern shown.

FIG. 3B is a cross-sectional view of the embodiment of FIG. 3A showing metal and dielectric patterns along line A-A of FIG. 3A.

FIG. 4A illustrates a prior art metal core substrate and a flip-chip power device.

FIG. 4B illustrates the prior art metal core substrate of FIG. 4A and a power device requiring wire-bonding.

FIG. 4C illustrates the flip-chip of FIG. 4A mounted on the prior art metal core substrate of FIG. 4A.

FIG. 4D illustrates the power device of FIG. 4B mounted on the prior art metal core substrate of FIG. 4B.

FIG. 4E illustrates a packaged LED mounted on the prior art metal core substrate of FIG. 4A.

FIG. 4F illustrates a power device assembly with thermal interface material (e.g., a metal epoxy) directly applied to a metal core substrate and a metal electrode layer provided over a laminated dielectric layer.

FIG. 5 illustrates the power device assembly of FIG. 4F mounted on a metal core substrate in accordance with the present invention.

FIG. 6 illustrates the relative thermal resistances of the structures of FIGS. 4C, 4F, and 5.

FIGS. 7A-7I illustrate variations of power device packages with over-mold protection, lens systems, and surface mountable external heat-sink devices for enhanced thermal dissipation, all in accordance with the present invention.

FIG. 7 A is a substrate in accordance with the present invention.

FIG. 7B is a package design embodiment with an over-mold compound, a cavity, and a clear protection material for the dice, in accordance with the present invention.

FIG. 7C is a package design embodiment with a pre-stamped metal base, a cavity, and a clear protection material for the dice, in accordance with the present invention.

FIG. 7D is a package design with a colored over-molded epoxy or a phosphor ceramic material, in accordance with the present invention.

FIG. 7E is a package design with an over-molded lens, in accordance with the present invention.

FIG. 7F is a package design with a separate dielectric layer at the bottom of the substrate, in accordance with the present invention.

FIG. 7G is a package design with no dielectric at the bottom of the substrate, in accordance with the present invention.

FIG. 7H is a package design with multiple devices on the metal core board for a motherboard application, including a 3D metal structure and prefabricated heat sink with a planar top surface, in accordance with the present invention.

FIG. 7I is a package design having a copper plated second face of the board that is directly soldered to a plated aluminum heat sink or a copper heat sink without thermal grease or thermal adhesive, in accordance with the present invention.

FIGS. 8A-8H show basic process steps to produce embedded dielectric areas that are planar with a metal layer using etching, deburring, or plating-up.

FIG. 9A illustrates copper plated up to be co-planar with an embedded or deposited raised dielectric layer.

FIG. 9B illustrates a dielectric sputtered into an etched surface of the metal substrate to achieve a planar surface.

FIGS. 10A-10E are cross-sectional views illustrating oxidizing grooves in the substrate for forming electrically isolated islands.

FIGS. 11A and 11B are perspective views illustrating various shapes of the grooves.

FIGS. 12A-12E are cross-sectional views illustrating oxidizing grooves in the substrate for forming electrically isolated islands or strips.

FIGS. 13A-13E are cross-sectional views illustrating forming insulated through-holes filled with copper for interconnecting metal layers on opposite surfaces of the substrate. The figures also illustrate selectively connecting thermal pads directly to the substrate.

FIG. 14 is a cross-sectional view illustrating how the metal substrate can form an electrically isolated via between metal layers on opposite surfaces of the substrate.

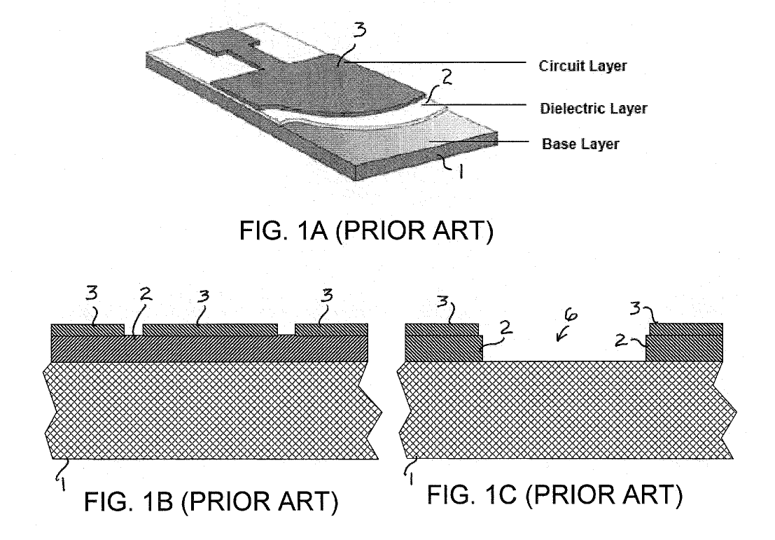

It is to be understood that these drawings are for illustrating the concepts of the invention and are not to scale. Elements that are similar or equivalent are labeled with the same numeral.

### DETAILED DESCRIPTION OF THE PREFERRED EMBODIMENTS

In accordance with the present invention, one product goal is to bring the thermal contact surface to be the same level as the electrical contact (co-planar). An anodization process is described for the dielectric layer; however, the co-planar selective insulation layer for defining the electrical path and the thermal path may be created using other techniques such as resin coating or plasma electrolytic oxidation, to name a few.

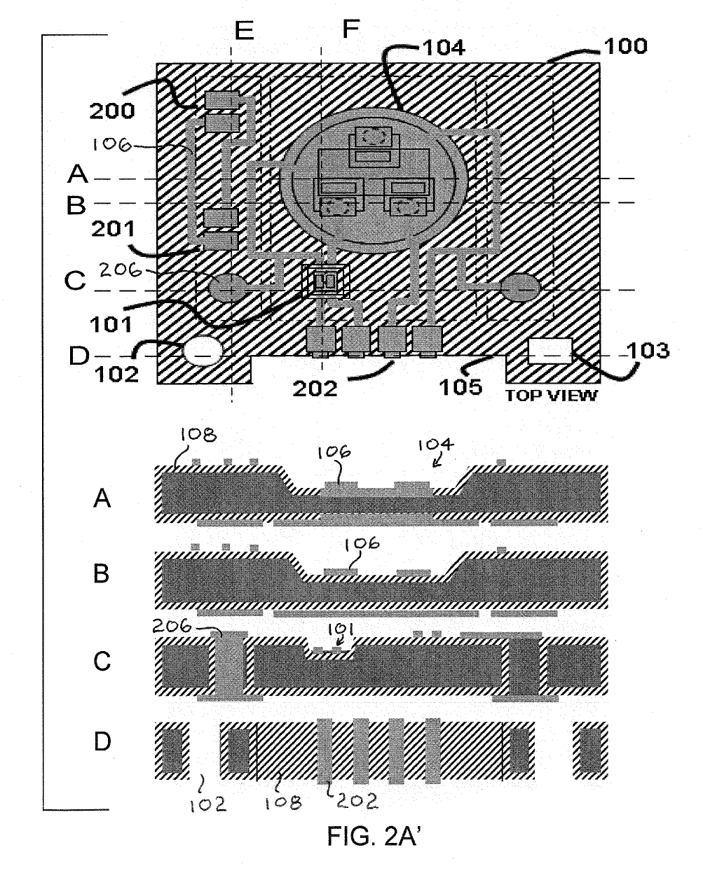

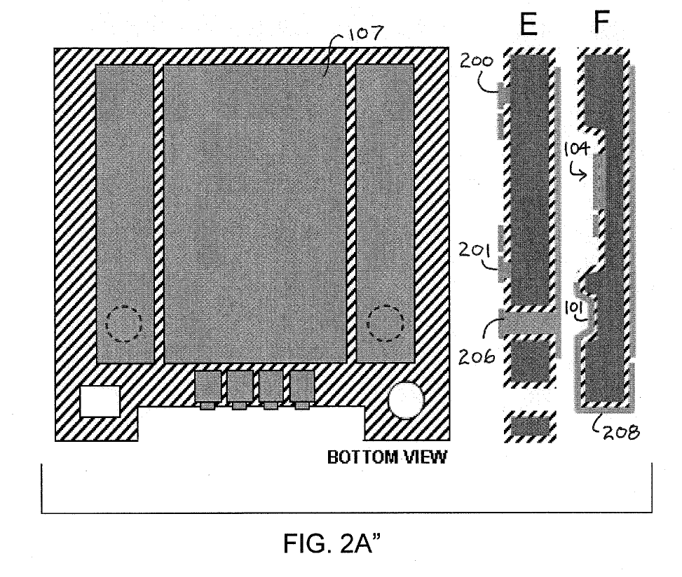

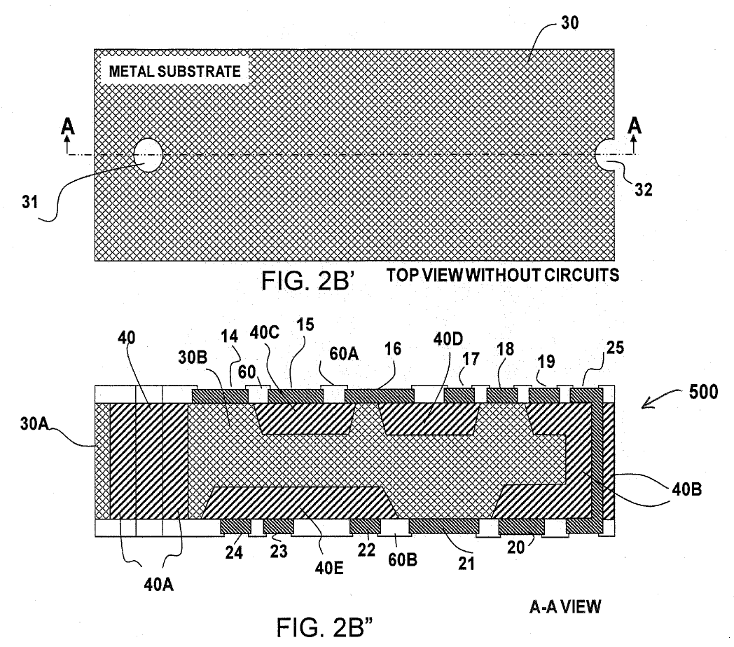

FIGS. 2A′ and 2A″ depict various connectivity possibilities of the present invention. The starting material can be a flat plate or multi-tier 3-dimensional metal substrate 100, such as aluminum. The metal substrate 100 can have pre-drilled through holes 102 and 103 and a pre-stamped cut-out 105. The various other features of the base metal may be formed by chemical etching, molding, machining, or other technique.

Cross-sections A-F across the top down view are shown in FIGS. 2A′ and 2A″.

Cavities 101 and 104 are shown in the cross-sections A, C, and F. The cavities 101 and 104 may be formed by selective etching of the metal substrate 100, using a conventional wet etchant. The cavity bases are at different depths as depicted in the cross-section F. Cavity 104 has the whole cavity coated with a reflective coating for light beam shaping purposes. The smaller cavity 101 can be used for embedded chips or as a base for tall chips which can otherwise create shadows for light emitting diode applications.

The same substrate 100 can have an anodized round hole 102 or square hole 103 for metal screws or connectors. The cut out 105 allows top-to-bottom circuit connections on the outside of the insulated wall. The two protruding arms of the cut-out 105 prevent side wall circuit shorting.

The top layer copper 106 is plated or sputtered over the metal substrate 100 and the dielectric layer 108 and copper layer portions can be connected to each other and to the bottom layer copper 107 by four different approaches.

(1) With the selective metallization, top copper pad 200 is electrically connected to the top copper pad 201 (cross-section E) via the body of the metal substrate 100, since there is no dielectric between the pads 200/201 and the body.

(2) Through-holes, formed by drilling, stamping, or chemical etching, are oxidized to insulate the walls of the holes, and the holes are filled with copper 206 (cross-section E) and 202 (cross-section D).

(3) Insulated copper pads are interconnected by copper metal traces on the surface of the dielectric layer 108.

(4) A top copper layer is connected to a bottom copper layer by an insulated sidewall copper path 208 in the cross-section F, where the sidewall of the substrate is first oxidized.

Various design techniques are shown in the A-F cross-sections of FIGS. 2A′ and 2A″.
A. Cavity with direct bulk body contact. Cavity acts as beam shaping or reflector cup for LED.
B. Cavity with insulated electrical contacts to all multi-level component assemblies.
C: Top-to-bottom metal layer connection by a two-via formation approach. The insulated via hole is plated.
D: Top-to-bottom copper layer connected by copper sidewalls.
E: Aluminum core as electrical conduits between copper pads.
F: Interconnected multilevel cavity structure allowing circuits to be connected via the cavity walls.

The following describes the implementation details of various embodiments.

FIG. 2B′ is a top view, only depicting the shape of the starting aluminum metal substrate 30 with optional differently shaped vertical holes 31 and 32. FIG. 2B″ is taken across the line A-A in FIG. 2B′ showing various circuits and dielectric layer patterns formed on the substrate 30. The entire device is a metal circuit board 500. Substrate portions 30A and 30B are shown in FIG. 2B″.

The metal circuit board 500 has opposing first and second faces. Formed on the surfaces of the substrate 30 are embedded dielectric layer portions 40C, 40D and 40E, shaped according to the insulation layer requirements. In one embodiment, the dielectric layer portions are masked anodized portions that form an aluminum oxide layer within the substrate 30. The surface can be planarized to cause any raised aluminum oxide to be co-planar with the surface of the substrate 30. In another embodiment, the areas for the dielectric layer can be etched to form indentations, and the indentations filled in with a resin, oxide, or other dielectric to be co-planar with the substrate 30 surface.

Optionally, a vertical oxide layer 40A and 40B can be formed in pre-stamped hole 40.

A copper layer 14-25 is then plated or sputtered on top of the insulation layer and patterned by etching or masking. As depicted in the embodiment, the copper layer 14-25 can selectively be plated on top of the insulation layer or plated on the metal surface without any insulation. One part of the copper layer 16 sits on the insulation layer and another part sits on the metal layer; thus forming the basis of direct thermal connection to the bulk metal and optionally acting as an electrical connection between the opposing faces.

Copper layer 18 is plated directly on the metal surface. Solder mask 60A and 60B is applied per IPC standard requirements and for lateral breakdown protection. The solder mask prevents solder from flowing laterally and shorting adjacent metal portions. A photoresist may be used as the solder mask, or other known material.

Copper layer 25 provides the insulated vertical circuit connection between the two opposing faces. Effectively, a multi-layer circuit is created.

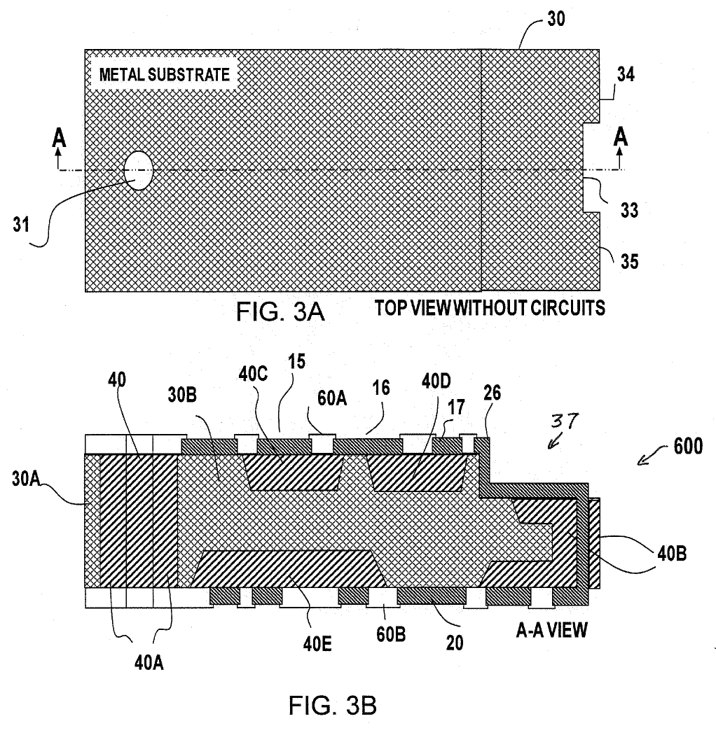

FIGS. 3A and 3B show another embodiment 600 with a three-dimension metal substrate. The cavity 37 may be formed by a wet etch (e.g., using an acid) prior to forming any other layers. The cavity 37 may also be formed by casting, milling, or other technique previously mentioned. Copper 26 is plated on the first face and extends around the side of the substrate 30 to terminate on the second face. Vertical walls 33, 34 and 35 (FIG. 3A) can be selectively insulated, such as by masking and oxidation. Wall 33 is then metallized with copper 26. The two protruding walls 34 and 35 will protect the copper 26 on wall 33. The same approach of insulation and metallization is applicable for a through-hole via.

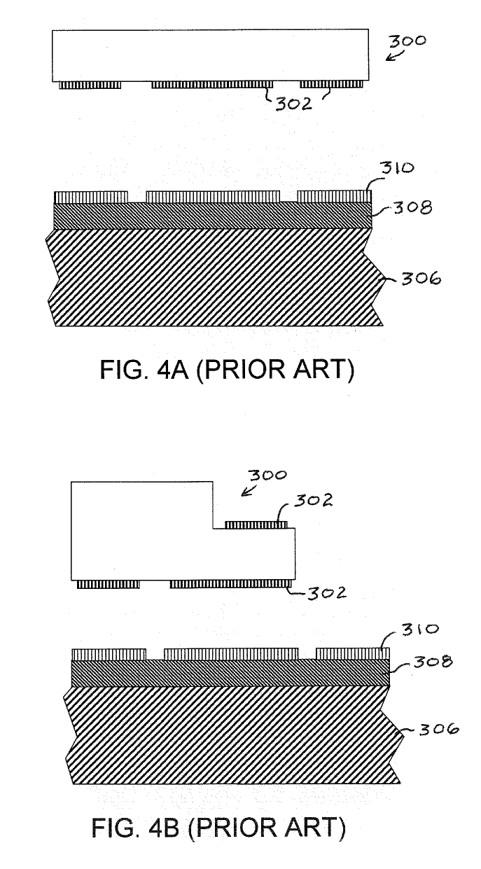

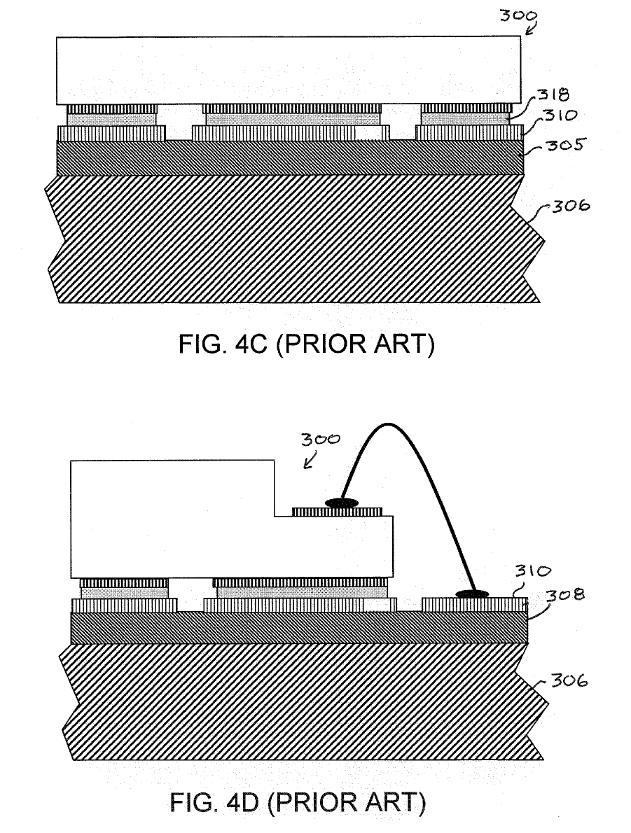

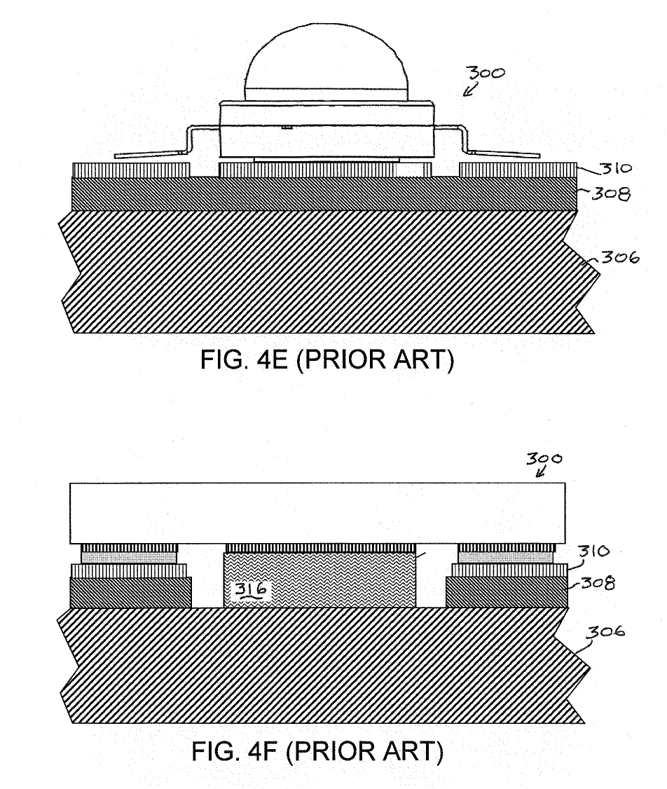

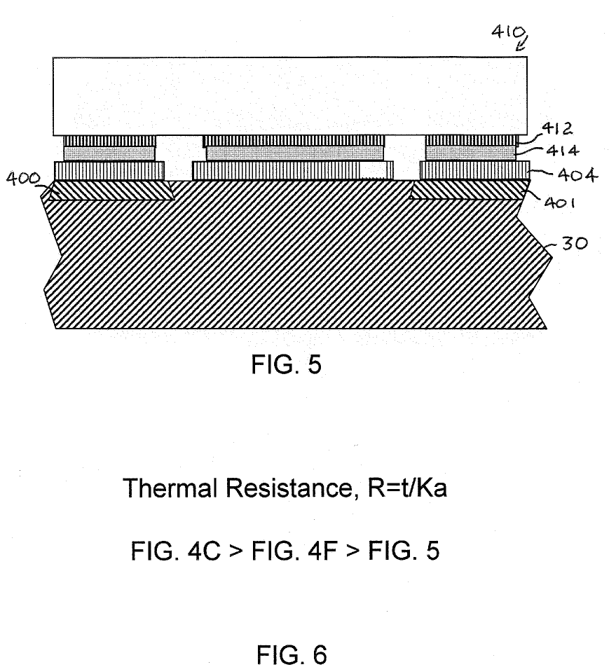

FIGS. 4A-4F are provided to simply show that the prior art generally uses laminated dielectric layers, and the top of the dielectric layer is not substantially co-planar with the metal surface of the core substrate.

In FIGS. 4A-4F, prior art heat-generating dies 300 of different types are shown having metal electrodes 302. The prior art metal core boards 306 are fabricated using the traditional laminated technology. Both the dielectric layer 308 and the copper foil 310 are physically laminated together with an adhesive which has varying degrees of glass transition temperatures. The adhesive absorbs moistures and it is sensitive to high temperature exposure which may result in lower copper to dielectric peel strength. Structurally, the typical dielectric has a thickness varying from 75 um to 150 um depending on the breakdown voltage requirement. The thermal resistance increases with the dielectric thickness.

Prior art FIG. 4F shows no dielectric between the die 300 and the metal substrate 306, and a metal epoxy or thermal grease is deposited between the die and the metal. This provides a good thermal path with low thermal resistance. Since the copper plane is overlying the dielectric, the thermal contact will be about the same height away from the metal core base. This topology requires very thick thermal interface material 316, and the soft thermal interface material 316 is squished down by the die 300 during the mounting process. Since thermal resistance is also pressure dependent; this topology is not suitable for surface mountable devices. The thermal interface material 316 is not co-planar with the copper layer. Solder 318 is shown in some embodiments interconnecting the die electrodes and substrate pads.

FIG. 5 shows an embodiment according to the current invention. FIG. 5 can be directly compared to prior art FIGS. 4C and 4F. The dielectric layers 400 and 401 are on the same plane as the surface of the aluminum substrate 30, resulting in a planar copper layer 404, even when the copper is plated directly on the aluminum substrate 30. The selective dielectric allows the copper layer 404 to be plated directly onto the metal base, providing the best thermal path with close to bulk material thermal conductivity. The heat generating die 410, which may be an IC, LED, etc., typically has co-planar bottom metal pads 412, including a central thermal pad that is electrically isolated. It is very easy to mount the die 410 to the co-planar copper layer 404 using solder 414, so the central thermal pad is thermally coupled to the metal substrate 30 with all metal, which is better than a thermal epoxy or grease. The bonding can also be performed by ultrasonic welding without solder.

FIG. 6 shows the relationships between FIGS. 4C, 4F, and 5 regarding the thermal resistance between the die and the metal substrate, illustrating that the co-planar copper electrode/thermal pad arrangement of FIG. 5 is the best embodiment. Since there is no laminated dielectric layer thickness between the plated copper and the metal base, the through-plane thermal resistance of the thermal path is close to the bulk thermal resistance, where the resistance R of the substrate is estimated to be ˜(t/kA) C/W, where t is the substrate thickness in meters, k is the material thermal conductivity in W/m−K, and A is the area of the heat source in m². The thermal conductivity for the aluminum alloy substrate ranges from 170 W/m−K to 230 W/m−K versus the more expensive ceramic at ˜30 W/m−K and about 0.3 W/m−K for FR4.

Besides the selective copper plating or sputtering, other types of electrically conductive material, like silver ink, may instead be used for the metallization interconnects. The present invention is specifically adapted to and has been described in connection with a flat plate metal base substrate but is not so limited. The invention can, in fact, be applied to substantially any metal substrate of various materials, particularly hybrid metal substrates or a metal finned heat sink with a flat interface for electrical connectivity.

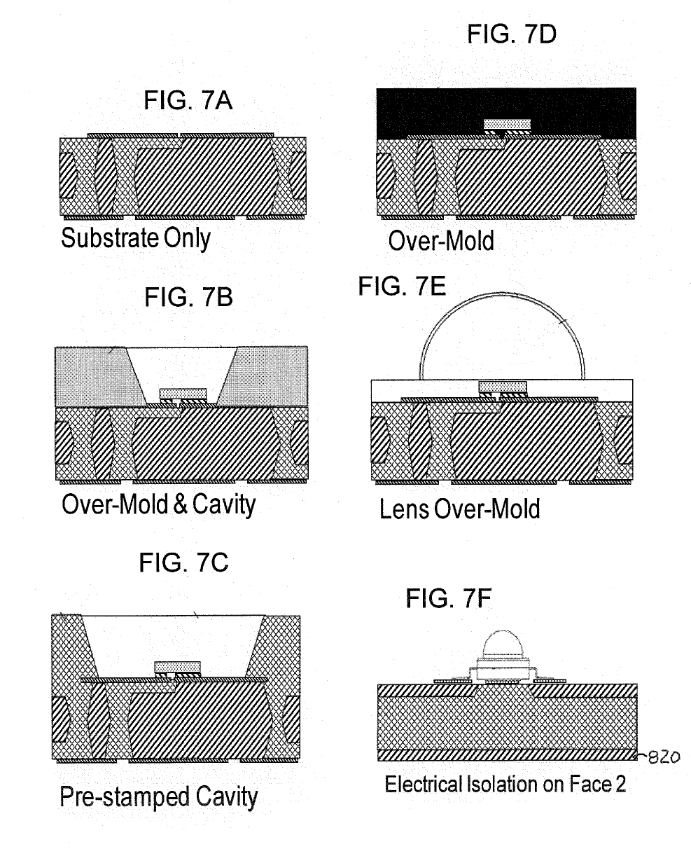

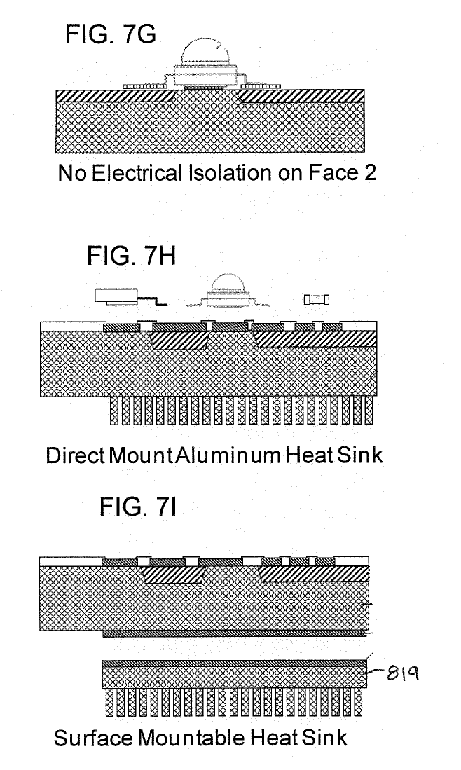

FIGS. 7A-7I illustrate different self-explanatory variations of metal substrates where a copper layer that forms both electrodes and thermal pads is co-planar for ease of mounting a die with co-planar electrodes and thermal pads. This is a result of the dielectric layer being co-planar with the metal substrate surface.

FIG. 7H shows the base material as an aluminum base heat sink with prefabricated fins. FIG. 7I shows an alternative embodiment of FIG. 7H, where the heat sink 819 can be made of copper instead of a plated aluminum heat sink, and then soldered or bolted onto a bottom copper layer on the aluminum substrate.

Specific to some LEDs wherein the LED heat slug in the package is not electrically isolated, a layer of oxide 820 (FIG. 7F) can be formed on the bottom face of the metal substrate. Structurally, this configuration will allow negligible thermal resistance between the heat slug and the bulk metal, resulting in better heat spreading. The bottom face electrical insulation layer as shown in FIG. 7F will provide unit level isolation when connected together in a matrix format.

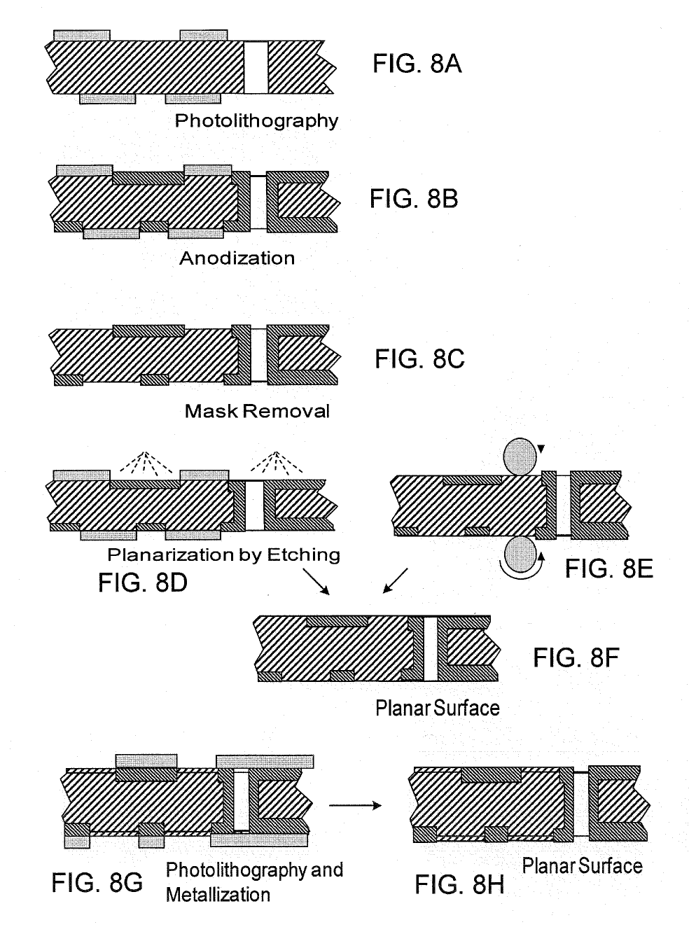

FIGS. 8A-8H show the various steps that may be used to create the dispersed dielectric layers within the aluminum base so that the dielectric is co-planar with the aluminum. FIGS. 8A-8C show the creation of the dielectric layer 800 by masking 801 the substrate using photolithography, followed by an oxidation/anodization process. Depending on anodization time, the dielectric layer 800 thickness and porosity can be controlled to suit breakdown voltage level requirement. At the end of the anodization process, the anodic coating (dielectric layer 800) will protrude slightly above the surface (FIG. 8C). The surface planarization can be accomplished by controlled oxide etching (FIG. 8D) or by mechanical deburring (FIGS. 8E, F) the top of the oxide layer or by plating-up (FIGS. 8G, H) around the oxide layer. The planar surface with embedded dielectric layer is ready for subsequent circuit fabrication processes.

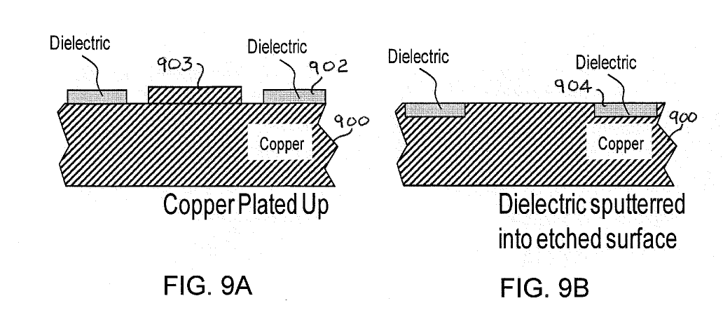

As shown in FIGS. 9A and 9B, the present invention can be implemented on a copper base 900. Copper has better thermal conductivity performance compared to aluminum. In FIG. 9A, the dielectric 902 is a raised layer, such as an oxidized layer than has not been planarized or a resin layer, and the copper 903 is plated up between the dielectric portions to be co-planar with the dielectric layer. In FIG. 9B, the dielectric 904 is either a planarized oxide layer or dielectric material deposited (e.g., sputtered or sprayed) in an etched, casted, or machined cavity of the substrate so that the dielectric and substrate surface are co-planar.

Aluminum oxide vertical growth can taper off after about 200 um. In other words, the oxide substantially stops growing beyond the 200 um thickness. For a two sided design, this translates to a total maximum oxide thickness of about 400 um when the top oxide connects to the bottom oxide. For an aluminum substrate thicker than 400 um, the top oxide cannot connect to the bottom oxide effectively. A 400 um substrate is relatively thin and does not have very good in-plane thermal spreading. Also, since the prior art must use thin substrates for such through-oxidation, such substrates become very weak since the oxide is brittle. The remainder of the substrate does not provide sufficient mechanical support for the circuit board.

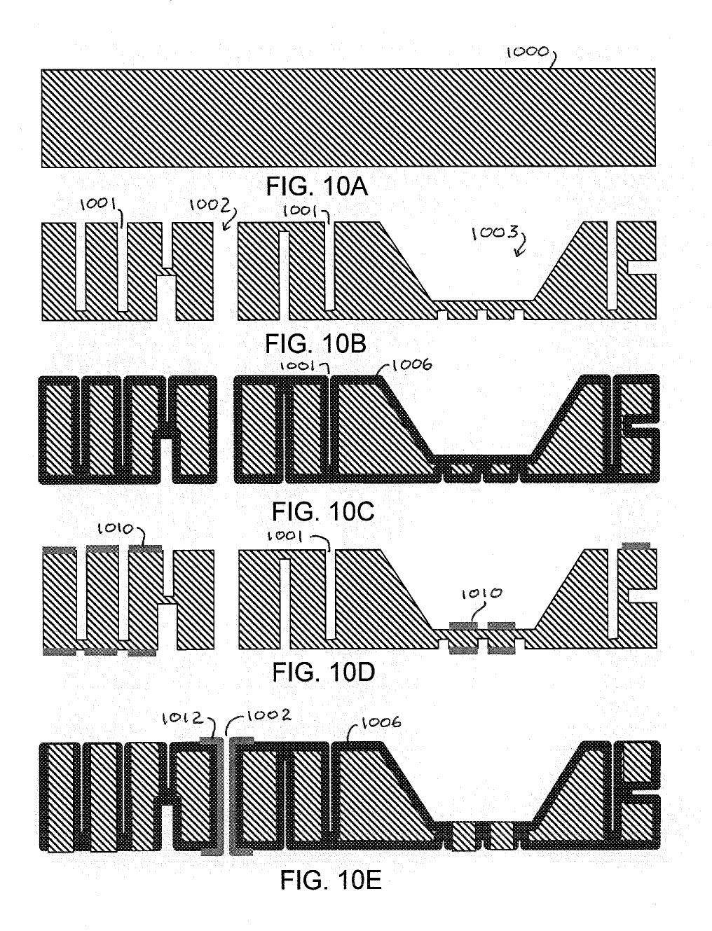

FIGS. 10A-10E and subsequent figures show another feature of the present invention wherein a metal substrate can be vertically isolated with a closed-loop oxidized groove to compensate for the oxide growing limitation. For example, if a 1000 um thick aluminum sheet is used as the substrate, a narrow 850 um deep route can be formed in the substrate's top surface to surround where a certain heat-generating component (e.g., an LED) will eventually be mounted. Sufficient metal is left to provide mechanical stability to the substrate. Accordingly, when oxidation of the groove is done in combination with selective bottom surface oxidation, the oxide will grow from the bottom to connect with the oxide growing inside the groove. Electrically isolated islands will thus be created. If the oxide along opposing surfaces of the groove does not merge, or the oxide is thick enough, there is high lateral thermal isolation of the island, yet high vertical conductivity to a heat sink. This is valuable to prevent the high heat from one component affecting the performance of other components on the same substrate. Vertical island isolation of any shape will add flexibility to thick substrate designs. The remaining portions of the thicker substrate provide mechanical stiffness to the circuit board.

More specifically, FIG. 10A illustrates an aluminum substrate 1000 of any thickness, such as 1000 um (1 mm).

The cross-section of FIG. 10B illustrates how the substrate 1000 has been either masked and chemically etched, casted, milled, or stamped to form grooves 1001, a through hole 1002, and a cavity 1003. The grooves 1001 will be used for electrical and thermal isolation; the through hole 1002 will be used for a conductive via between the top and bottom surface; and the cavity 1003 will be used to form a reflector for an LED.

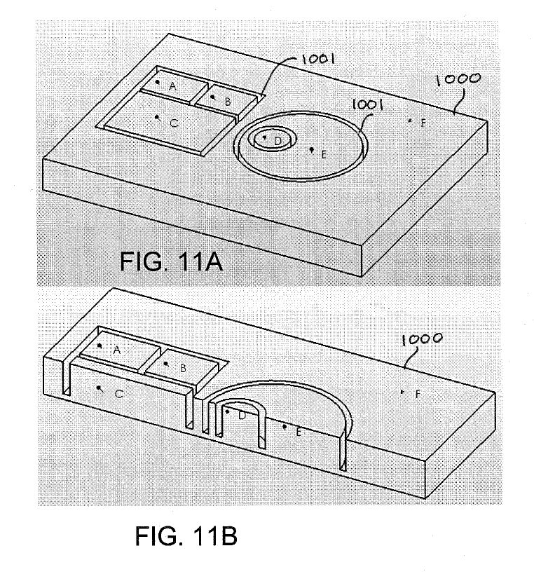

The wide variety of features of FIG. 10B are just for illustration. FIGS. 11A and 11B are perspective and cut-away views of other shaped grooves 1001 formed in a substrate 1000 that can be used to electrically isolate areas A-F.

FIG. 10C illustrates that the entire substrate 1000 has been oxidized by any of a variety of known processes. One suitable process is anodizing the aluminum. Anodizing involves placing the aluminum into a chemical acid bath, such as sulfuric acid. The aluminum becomes the positive anode of a chemical battery and the acid bath becomes the negative. An electric current passes through the acid, causing the surface of the aluminum to oxidize. The oxidized aluminum forms a strong coating as it replaces the original aluminum on the surface. The duration of the process determines the aluminum oxide thickness. In FIG. 10C, the up-down oxide 1006 is formed thick enough to merge at the bottom of each groove 1001 for electrical isolation. If the oxide on opposing sides of the groove does not merge, lateral thermal resistance is very high.

FIG. 10D illustrates how, instead of the blanket oxidation of the substrate 1000 in FIG. 10C, the substrate 1000 may be selectively masked using conventional masking material 1010, and then subjected to the anodization process. FIG. 10E illustrates the resulting substrate 1000, where oxide is not grown where the masking material 1010 was located. FIG. 10E also shows that the through-hole 1002 has been plated with copper 1012 for providing a conductive via between a top metal layer and a bottom metal layer.

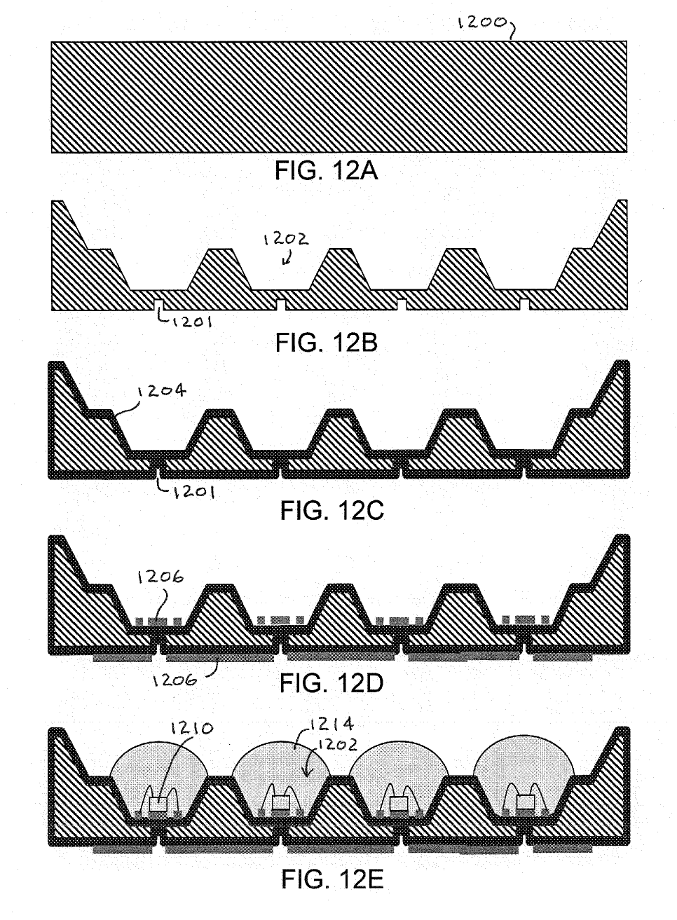

FIGS. 12A-12E illustrate a process similar to FIGS. 10A-10C for a realistic use as a circuit board for LEDs. When arrays of LEDs are mounted on a single metal circuit board, the LEDs are typically interconnected, and the heat generated by one LED should ideally not interfere with the operation of any other LED. FIGS. 12A-E and subsequent figures address the problem with arrays of LEDs. The design goals are:
(i) A large panel one-piece metal substrate with multiple arrays for LED chip-on-board assembly;
(ii) An individual array has a thin metal base of less than 300 um in certain regions and thicker material in other regions for mechanical strength. The thin region is for chip-on-board die assembly to allow rapid heat conduction to the external heat sink (such as shown in FIG. 7I);
(iii) A stamped or milled or chemically etched cavity for each LED die to enhance light output or beam shaping;
(iv) Copper metallization on the thermal pads with direct metal contact to the metal core to allow solder as the thermal interface to further reduce thermal resistance;
(v) Copper metallization on the dielectric layer for electrical traces;
(vi) Optional surface mount interconnects from top surface to bottom surface for array assembly to end applications;
(vii) Vertical thermal isolation between arrays so that multiple arrays can be fabricated on the same large panel without affecting one another. The thermal isolation between arrays is especially important during testing or burn-in purposes when all LEDs are powered up at the same time and lateral heat transfer between arrays should be minimized.

Consequently, LEDs in arrays can be produced in Large Panel format consisting of many sub-arrays; thus improving manufacturing cost, and LEDs in arrays or individual units may be operated at higher currents. Thus, the inventive LED arrays may provide more flux per unit area than is provided by conventional LED arrays.

In FIGS. 12A and 12B, an aluminum substrate 1200 has formed in it grooves 1201, cavities 1202, and other features. In FIG. 12C, the substrate surface is anodized so that the up-down oxide 1204 merges at the bottom of the grooves 1201 for electrical isolation.

In FIG. 12D, copper 1206, or other metal, is selectively plated or sputtered onto the oxide 1204 using known techniques. Outside of the plane of the figures, the copper 1206 forms traces that may interconnect the LEDs such as in series and/or parallel. Also outside the plane of the figure, the metal substrate is thicker in at least the outer areas to maintain structural stability. Copper 1206 is also plated on the bottom of the substrate. Such bottom copper can be used as a thermal interface to a heat sink, such as shown in FIG. 7I, or the bottom copper may form bottom electrodes connected to the top surface copper by conductive vias through the substrate 1200. The vias may just be plated holes through the substrate 1200.

In FIG. 12E, LED dies 1210 are mounted onto the substrate 1200 so as to be thermally coupled to a copper pad and electrically coupled to copper electrodes. The oxidized grooves 1201 are formed in strips or in rectangles to electrically isolate individual LEDs or groups of LEDs, as required for the series connection. The cavity 1202 may have a reflective coating and is filled with a lens material 1214, such as silicone. Also, due to the thinness of the bottom floor of the cavity 1202, there is very little thermal resistance between the LED dies 1210 and a heat sink (not shown) connected to the bottom of the substrate 1200.

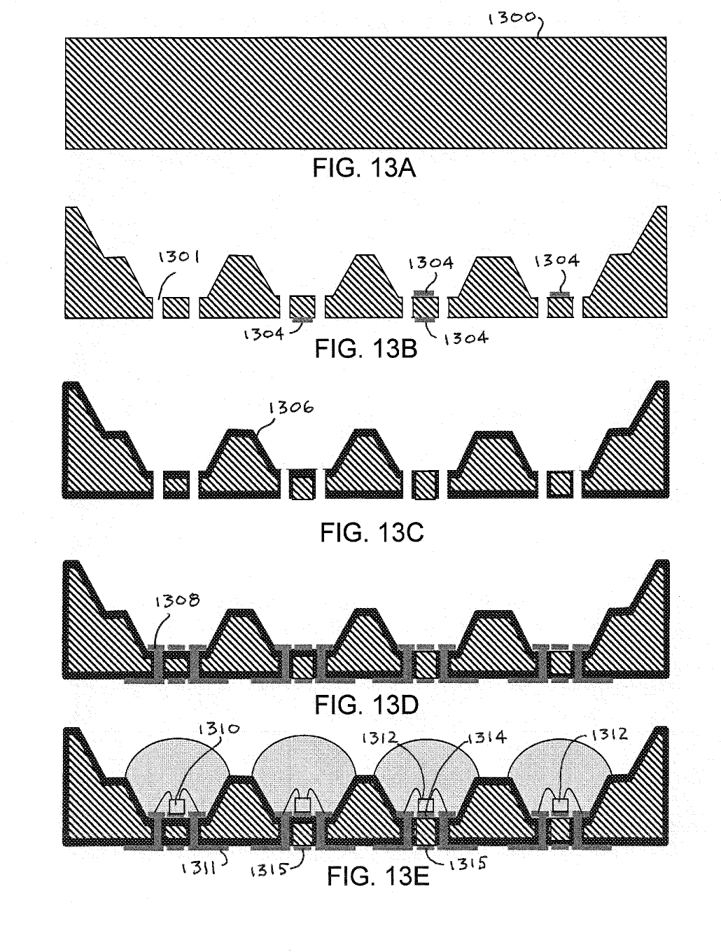

FIGS. 13A-E illustrate how conductive via connections may be made through the aluminum substrate 1300 and how the thermal pads can be either directly formed over oxide or over the aluminum.

In FIG. 13B, through-holes 1301 and other features are formed in the substrate 1300. Some surfaces are selectively masked by a masking material 1304 to prevent oxidation of those surfaces.

FIG. 13C illustrates the resulting oxide 1306 being formed on the non-masked surfaces.

FIG. 13D illustrates selective copper 1308 plating in the oxidized through-holes 1301 and over some oxidized and non-oxidized surfaces.

FIG. 13E illustrates how LED dies 1310 are electrically bonded to the electrically isolated copper that is connected to bottom electrodes 1311 by the filled through-holes. FIG. 13E also shows that some LED dies 1312 have their thermal pad connected to a copper thermal pad 1314 that is in direct contact with the aluminum for improved thermal conduction to an underlying heat sink (not shown). Also shown is a bottom thermal pad 1315 directly plated over the aluminum for improved thermal conductivity to the heat sink. Alternatively, the thermal pads and heat sink may be insulated from the substrate by ensuring that a dielectric layer exists between the heat sink and the substrate.

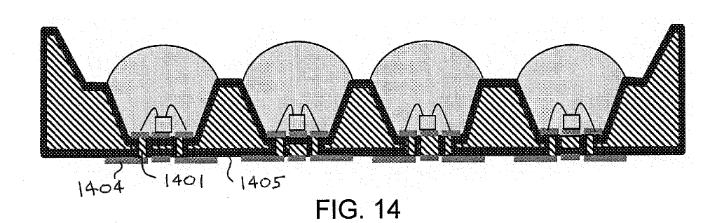

FIG. 14 illustrates that the aluminum itself can form an isolated via 1401 between top and bottom copper electrodes 1404. The top and bottom areas of the via 1401 are masked during anodization to later allow direct contact of the copper electrodes to the aluminum. There are no through-holes formed in FIG. 14. In FIG. 14, the substrate is made thinner beneath some LEDs for allowing the oxide 1405 from the bottom and top to quickly merge. This also improves thermal conductivity to a heat sink. FIG. 14 also shows some thermal pads electrically insulated from the substrate and not insulated from the substrate.

For high volume and cost effective manufacturing, multiple LED arrays are produced at the same time in large panel format similar to a semiconductor wafer fabrication process.

A single array of LEDs may be 4 inches by 4 inches with many LED dies. A large panel may comprise many sub-arrays, where the LEDs in a sub-array are connected in series, and the sub-arrays connected in parallel. To allow large panel production, the same 4×4 inch array pattern can be repeated over the large panel, say with 9 sub-arrays. The lithography or masking process is the same for a 4×4 inch panel or a large panel. The rest of the processes like anodization, etching, etc can be done at the large panel level, thus, reducing the overall cost. For testing purposes, the large panel with multiple arrays requires thermal isolation between sub-arrays since all LEDs may be turned on concurrently. Thus, the thermal isolation provided by the present invention prevents thermal interactions between arrays.

Although aluminum has been used as the preferred example of a substrate due to is low expense and ease of anodizing, other metals may also be used such as copper, magnesium, titanium, beryllium, nickel, and alloys of any of the metals mentioned herein.

The dielectric may also be aluminum nitride instead of aluminum oxide.

When an aluminum oxide is formed, it becomes porous. A dielectric resin may be applied to the aluminum oxide that seeps into the pores and becomes strongly bonded to the substrate. The resin seals the substrate.

It is understood that the above-described embodiments are illustrative of only a few of the many possible specific embodiments which can represent applications of the invention. The same metal core substrate or metal core printed circuit board can be used for power electronic devices and multi-chip module and system level motherboard applications. Numerous and other varied arrangements can be made by those skilled in the art without departing from the spirit and scope of the invention.

What is claimed is:

1. A circuit board comprising:
a metal substrate having a first surface and an opposing second surface;
a groove formed in the first surface, the groove not extending totally through a thickness of the substrate;
a first oxide portion formed at least in a bottom surface of the groove, the groove being formed prior to growing the first oxide;
a second oxide portion formed in second surface of the substrate opposing the bottom surface of the groove, wherein the first oxide portion and second oxide portion have grown toward one another and merge below the bottom surface of the groove; and
the groove, the first oxide portion, and the second oxide portion electrically isolating an electrical component bordered by the groove.

2. The circuit board of claim 1 wherein the groove is circular.

3. The circuit board of claim 1 wherein the groove is rectangular.

4. The circuit board of claim 1 wherein the groove extends greater than 50% through the thickness of the substrate.

5. The circuit board of claim 1 wherein the substrate comprises aluminum and the first oxide portion and second oxide portion comprises aluminum oxide.

6. The circuit board of claim 1 wherein there are multiple grooves formed in the first surface and each are oxidized to create electrically isolated portions in the substrate, and wherein an electrical component is mounted in each electrically isolated portion.

7. The circuit board of claim 1 further comprising cavities formed in the substrate that are oxidized along with the groove for electrical insulation.

8. The circuit board of claim 1 further comprising a through-hole formed in the substrate that is coated, at least along walls of the through-hole, with a metal for electrically connecting a metal layer over the first surface with a metal layer over the second surface.

9. The circuit board of claim 1 wherein oxide on opposing walls of the groove do not merge together.

10. The circuit board of claim 1 wherein the groove is a first groove, and wherein a second groove is formed in the second surface opposing the first groove, the second groove being oxidized to form the second oxide portion in the second groove that merges with the first oxide portion in the first groove.

11. The circuit board of claim 1 wherein the groove borders the electrical component, wherein the electrical component has an electrically insulated thermal pad that thermally contacts the substrate without any oxide between the thermal pad and the substrate, and wherein the electrical component has electrodes that contact metal electrodes on the first surface that are electrically insulated from the substrate by an oxide layer grown in the first surface.

12. A circuit board comprising:
a metal substrate having a first surface and an opposing second surface;
a hole formed completely through the substrate;
an oxide coating walls of the hole;
a first metal deposited in the hole, the first metal being electrically isolated from the metal substrate by the oxide;
a first metal layer formed over the first surface for connection to an electrode of an electrical component; and
a second metal layer formed over the second surface, the first metal deposited in the hole electrically connecting the first metal layer to the second metal layer.

13. A circuit board comprising:
a metal substrate having a first surface and an opposing second surface;
a first metal layer formed over the first surface for connection to an electrode of an electrical component;
a second metal layer formed over the second surface;
a first metal formed over a sidewall of the substrate and insulated from the substrate by an oxide layer formed over the sidewall, the first metal electrically connecting the first metal layer to the second metal layer.

14. The circuit board of claim 13 wherein the substrate has a notch formed in its side, the first metal being formed in the notch so as to be protected by one or more protruding portions of the substrate bordering the notch.

15. A circuit board comprising:
a metal substrate having a first surface and an opposing second surface;
a non-laminated dielectric layer formed on the first surface, a top surface of the dielectric layer extending above a top surface area of the substrate where there is no dielectric layer; and
a metal layer directly formed over the top surface area of the substrate where there is no dielectric layer to make a top surface of the metal layer co-planar with the top surface of the dielectric layer.

16. The circuit board of claim 15 wherein the dielectric layer is an oxidized layer or a sputtered dielectric layer.

17. A circuit board comprising:
a metal substrate having a first surface and an opposing second surface, the first surface being formed to have a cavity;
a dielectric formed in the cavity to have a top surface coplanar with a surrounding first surface of the substrate; and
a metal layer at least formed over the dielectric for connection to an electrical component.

18. The circuit board of claim 17 wherein the dielectric is an oxidized layer or a sputtered layer.

19. A method of manufacturing a circuit board comprising:
providing a metal substrate having a first surface and an opposing second surface;
oxidizing a portion of the top surface to form a dielectric layer, a top surface of the dielectric layer extending above a top surface area of the substrate where there is no dielectric layer; and
planarizing the top surface of the dielectric layer to make the top surface co-planar with the top surface area of the substrate where there is no dielectric layer.

20. The method of claim 19 wherein planarizing the top surface of the dielectric comprises etching or mechanically removing a top portion of the dielectric.
